(19) United States
(12) Patent Application Publication
(10) Pub. No.: US 2023/0280411 A1
(43) Pub. Date: Sep. 7, 2023

(54) METHODS AND SYSTEMS FOR DETERMINING A WEAK CELL OF A BATTERY

(71) Applicant: Astrolabe Analytics, Inc., Seattle, WA (US)

(72) Inventors: Robert Masse, Seattle, WA (US); Shrilakshmi Bonageri, Karnataka (ID); Daniel E. Shea, Seattle, WA (US)

(73) Assignee: Astrolabe Analytics, Inc., SEATTLE, WA (US)

(21) Appl. No.: 17/943,327

(22) Filed: Sep. 13, 2022

Related U.S. Application Data
(60) Provisional application No. 63/243,257, filed on Sep. 13, 2021.

(51) Int. Cl. G01R 31/396; G01R 31/385; G01R 31/367; H01M 10/48; H01M 50/211

(52) U.S. Cl. CPC G01R 31/396; G01R 31/367; G01R 31/385; H01M 10/482; H01M 50/211

(57) ABSTRACT

Aspects relate to methods and systems for detecting a weak cell of a battery. The system including a battery including a plurality of cells, a plurality of sensors configured to detect a potential of each cell of the plurality of cells over time for a duration, and a computing device configured to receive the potential of each cell of the plurality of cells, determine at least an outlier cell from the plurality of cells, as a function of the potential of each cell of the plurality of cells, and filter the at least a weak cell as a function of the at least an outlier cell.

### CROSS-REFERENCE TO RELATED APPLICATIONS

This application claims the benefit of priority of U.S. Provisional Pat. Application Serial No. 63/243,257 filed on Sep. 13, 2021 and entitled “METHODS AND SYSTEMS FOR DETERMINING A WEAK CELL OF A BATTERY,” which is incorporated by reference herein in its entirety.

### FIELD OF THE INVENTION

The present invention generally relates to the field of electrochemical battery analysis. In particular, the present invention is directed to methods and systems for determining a weak cell of a battery.

### BACKGROUND

Presently, non-renewable fossil fuels provide most of the energy for many industries, including human transport. While renewable energy sources exist, their adoption has been slowed, in part because of difficulties associated with energy storage, such as multi-cell batteries. There is a need for technology capable of determining a weak cell of a battery.

### SUMMARY OF THE DISCLOSURE

In an aspect a system for determining at least a weak cell of at least a battery includes. The system including a battery including a plurality of cells, a plurality of sensors configured to detect a potential of each cell of the plurality of cells over time for a duration, and a computing device configured to receive the potential of each cell of the plurality of cells, determine at least an outlier cell from the plurality of cells, as a function of the potential of each cell of the plurality of cells, and filter the at least a weak cell as a function of the at least an outlier cell.

In another aspect a method of determining at least a weak cell of at least a battery. The method including detecting, using a plurality of sensors, a potential of each cell of a plurality of cells of a battery over time for a duration, receiving, using a computing device, the potential of each cell of the plurality of cells, determining, using the computing device, at least an outlier cell from the plurality of cells, as a function of the potential of each cell of the plurality of cells, and filtering, using the computing device, the at least a weak cell as a function of the at least an outlier cell.

These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a block diagram illustrating an exemplary system for determining a weak cell of a battery;

FIG. 2 is a graph of potential over time for an exemplary battery;

FIG. 3 is graph of potential over time for an exemplary battery;

FIG. 4 is a graph representing potential integral and minimum voltage for an exemplary battery;

FIG. 5 is a graph representing outlier cells for an exemplary battery;

FIG. 6 is a graph representing weak cells for an exemplary battery;

FIG. 7 is a block diagram illustrating exemplary machine-learning processes;

FIG. 8 is a flow diagram illustrating an exemplary method of determining a weak cell of a battery; and

FIG. 9 is a block diagram of a computing system that can be used to implement any one or more of the methodologies disclosed herein and any one or more portions thereof.

The drawings are not necessarily to scale and may be illustrated by phantom lines, diagrammatic representations and fragmentary views. In certain instances, details that are not necessary for an understanding of the embodiments or that render other details difficult to perceive may have been omitted.

### DETAILED DESCRIPTION

At a high level, aspects of the present disclosure are directed to systems and methods for determining a weak cell of a battery. In an embodiment, at least a weak cell of a battery may be determined after collecting data from the battery for only a relatively short duration, while the battery is being discharged.

Aspects of the present disclosure can be used to determine at least a weak cell of a battery prior to substantial use of the battery. Aspects of the present disclosure can also be used to aid in fuel gauging battery and making determinations about battery life. This is so, at least in part, because, in some cases, a multi-cell battery’s performance is limited by its weakest cell.

Aspects of the present disclosure allow for determination of weakest cells within a battery, which allow for predictive models using the performance characteristic from the weakest cells to be used to predict performance of the battery. Exemplary embodiments illustrating aspects of the present disclosure are described below in the context of several specific examples.

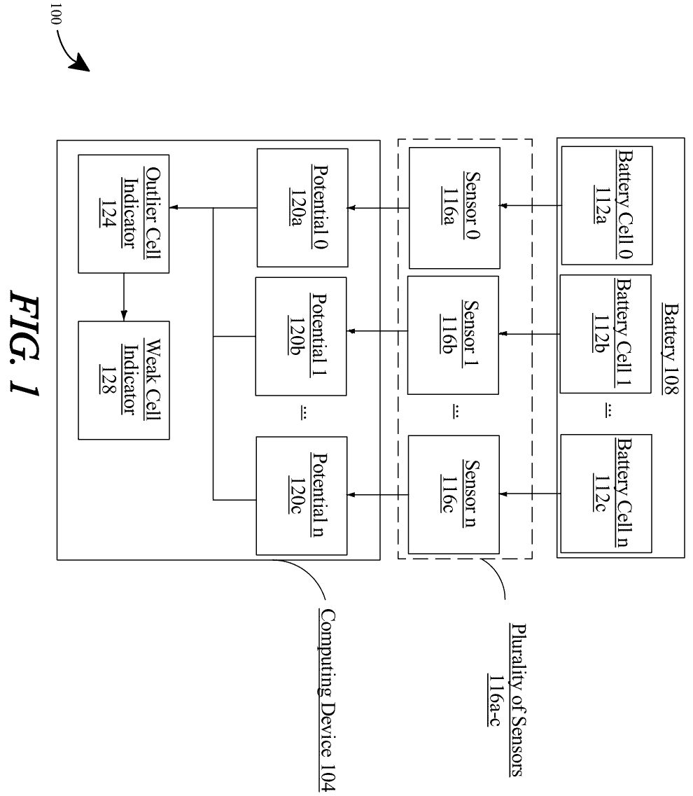

Referring now to FIG. 1, an exemplary embodiment of a system 100 for determining at least a weak cell of a battery is illustrated. System includes a computing device 104. Computing device 104 may include any computing device as described in this disclosure, including without limitation a microcontroller, microprocessor, digital signal processor (DSP) and/or system on a chip (SoC) as described in this disclosure. 104. Computing device 104 may include a processor and a memory communicatively connected to the processor, wherein memory contains instructions configuring processor to determine a weak cell of a battery. As used in this disclosure, “communicatively connected” means connected by way of a connection, attachment, or linkage between two or more relata which allows for reception and/or transmittance of information therebetween. For example, and without limitation, this connection may be wired or wireless, direct, or indirect, and between two or more components, circuits, devices, systems, and the like, which allows for reception and/or transmittance of data and/or signal(s) therebetween. Data and/or signals therebetween may include, without limitation, electrical, electromagnetic, magnetic, video, audio, radio, and microwave data and/or signals, combinations thereof, and the like, among others. A communicative connection may be achieved, for example and without limitation, through wired or wireless electronic, digital, or analog, communication, either directly or by way of one or more intervening devices or components. Further, communicative connection may include electrically coupling or connecting at least an output of one device, component, or circuit to at least an input of another device, component, or circuit. For example, and without limitation, via a bus or other facility for intercommunication between elements of a computing device. Communicative connecting may also include indirect connections via, for example and without limitation, wireless connection, radio communication, low power wide area network, optical communication, magnetic, capacitive, or optical coupling, and the like. In some instances, the terminology “communicatively coupled” may be used in place of communicatively connected in this disclosure.

Still referring to FIG. 1, computing device 104 may include, be included in, and/or communicate with a mobile device such as a mobile telephone or smartphone. Computing device 104 may include a single computing device operating independently, or may include two or more computing device operating in concert, in parallel, sequentially or the like; two or more computing devices may be included together in a single computing device or in two or more computing devices. Computing device 104 may interface or communicate with one or more additional devices as described below in further detail via a network interface device. Network interface device may be utilized for connecting computing device 104 to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network may employ a wired and/or a wireless mode of communication. In general, any network topology may be used. Information (e.g., data, software etc.) may be communicated to and/or from a computer and/or a computing device. Computing device 104 may include but is not limited to, for example, a computing device or cluster of computing devices in a first location and a second computing device or cluster of computing devices in a second location. Computing device 104 may include one or more computing devices dedicated to data storage, security, distribution of traffic for load balancing, and the like. Computing device 104 may distribute one or more computing tasks as described below across a plurality of computing devices of computing device, which may operate in parallel, in series, redundantly, or in any other manner used for distribution of tasks or memory between computing devices. Computing device 104 may be implemented using a “shared nothing” architecture in which data is cached at the worker, in an embodiment, this may enable scalability of system 100 and/or computing device.

With continued reference to FIG. 1, computing device 104 may be designed and/or configured to perform any method, method step, or sequence of method steps in any embodiment described in this disclosure, in any order and with any degree of repetition. For instance, computing device 104 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Computing device 104 may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

With continued reference to FIG. 1, system 100 includes a battery 108. Alternatively or additionally, in some cases, system 100 may be substantially remote from battery 108. A “battery,” as used in this disclosure, is a power source. Battery 108 may include a plurality of battery cells 112a-c. As used in this disclosure, a “battery cell” also referred to as a “cell” as used in this disclosure, is an electrochemical device capable of generating electrical energy from chemical reactions. In some cases, battery 108 may include a plurality of cells. In some cases, a cell may itself include a plurality of cells. For example, in some cases, a cell may be a pack of cells, which may also be referred to in this disclosure as a “battery module.” In some cases, battery 108 may include a lithium (Li) ion battery. Li ion batteries may include NCA, NMC, Lithium iron phosphate (LiFePO4) and Lithium Manganese Oxide (LMO) batteries, which may be mixed with another cathode chemistry to provide more specific power. For example, Li metal batteries have a lithium metal anode that provides high power on demand. In some cases, Li ion batteries having a silicon or titanite anode, energy source may be used. Battery 108 may include, without limitation a battery using nickel based chemistries such as nickel cadmium or nickel metal hydride, a battery using lithium ion battery chemistries such as a nickel cobalt aluminum (NCA), nickel manganese cobalt (NMC), lithium iron phosphate (LiFePO4), lithium cobalt oxide (LCO), and/or lithium manganese oxide (LMO), a battery using lithium polymer technology, lead-based batteries such as without limitation lead acid batteries, metal-air batteries, or any other suitable battery. Persons skilled in the art, upon reviewing the entirety of this disclosure, will be aware of various devices of components that may be used as an energy source.

With continued reference to FIG. 1, in some cases cells 112a-c may include pouch cells 112a-c. As used in this disclosure, a “pouch cell” is a battery cell or module that includes a pouch. In some cases, a pouch cell may include or be referred to as a prismatic pouch cell, for example when an overall shape of pouch is prismatic. In some cases, a pouch cell may include a pouch which is substantially flexible. Alternatively or additionally, in some cases, pouch may be substantially rigid. Pouch cell may include at least a pair of electrodes. At least a pair of electrodes may include a positive electrode and a negative electrode. Each electrode of at least a pair of electrodes may include an electrically conductive element. Non-limiting exemplary electrically conductive elements include braided wire, solid wire, metallic foil, circuitry, such as printed circuit boards, and the like. At least a pair of electrodes may be in electric communication with and/or electrically connected to at least a pair of foil tabs. At least a pair of electrodes may be bonded in electric communication with and/or electrically connected to at least a pair of foil tabs by any known method, including without limitation welding, brazing, soldering, adhering, engineering fits, electrical connectors, and the like. In some cases, at least a pair of foil tabs may include a cathode and an anode. In some cases, an exemplary cathode may include a lithium-based substance, such as lithium-metal oxide, bonded to an aluminum foil tab. In some cases, an exemplary anode may include a carbon-based substance, such as graphite, bonded to a copper tab. A pouch cell may include an insulator layer. As used in this disclosure, an “insulator layer” is an electrically insulating material that is substantially permeable to battery ions, such as without limitation lithium ions. In some cases, insulator layer may be referred to as a separator layer or simply separator. In some cases, insulator layer may be configured to prevent electrical communication directly between at least a pair of foil tabs (e.g., cathode and anode). In some cases, insulator layer may be configured to allow for a flow ions across it. Insulator layer may consist of a polymer, such as without limitation polyolefin (PO). Insulator layer may comprise pores which are configured to allow for passage of ions, for example lithium ions. In some cases, pores of a PO insulator layer may have a width no greater than 100 µm, 10 µm, 1 µm, or 0.1 µm. In some cases, a PO insulator layer may have a thickness within a range of 1 - 100 µm, or 10 - 50 µm.

With continued reference to FIG. 1, pouch cell 112a-c may include a pouch. Pouch may be configured to substantially encompass at least a pair of foil tabs and at least a portion of insulator layer. In some cases, pouch may include a polymer, such as without limitation polyethylene, acrylic, polyester, and the like. In some case, pouch may be coated with one or more coatings. For example, in some cases, pouch may have an outer surface coated with a metalizing coating, such as an aluminum or nickel containing coating. In some cases, pouch coating be configured to electrically ground and/or isolate pouch, increase pouches impermeability, increase pouches resistance to high temperatures, increases pouches thermal resistance (insulation), and the like. An electrolyte is located within pouch. In some cases, electrolyte may comprise a liquid, a solid, a gel, a paste, and/or a polymer. Electrolyte may wet or contact one or both of at least a pair of foil tabs.

System 100 utilizes computing device 104 to determine at least a weak cell from plurality of cells 112a-c. As used in this disclosure, a “weak cell” of a battery is a cell having open circuit voltage after use of battery that is lower than other cells of the battery. In some cases, a weakest cell may have lowest open circuit voltage after use of battery. Battery 108 is a power source that may be configured to store electrical energy in the form of a plurality of battery modules, which themselves include of a plurality of electrochemical cells 112a-c. These cells 112a-c may utilize electrochemical cells, galvanic cells, electrolytic cells, fuel cells, flow cells, and/or voltaic cells. In general, an electrochemical cell is a device capable of generating electrical energy from chemical reactions or using electrical energy to cause chemical reactions, this disclosure will focus on the former. Voltaic or galvanic cells are electrochemical cells that generate electric current from chemical reactions, while electrolytic cells generate chemical reactions via electrolysis. In general, the term ‘battery’ is used as a collection of cells connected in series or parallel to each other. A battery cell, when used in conjunction with other cells, may be electrically connected in series, in parallel or a combination of series and parallel. Series connection includes wiring a first terminal of a first cell to a second terminal of a second cell and further configured to include a single conductive path for electricity to flow while maintaining the same current (measured in Amperes) through any component in the circuit. A battery cell may use the term ‘wired’, but one of ordinary skill in the art would appreciate that this term is synonymous with ‘electrically connected’ or in ‘electrical communication’ with, and that there are many ways to couple electrical elements like battery cells together. An example of a connector that does not include wires may be prefabricated terminals of a first gender that mate with a second terminal with a second gender. Battery cells may be wired in parallel. Parallel connection includes wiring a first and second terminal of a first battery cell to a first and second terminal of a second battery cell and further configured to include more than one conductive path for electricity to flow while maintaining substantially the same potential (measured in Volts) across any component in the circuit. Battery cells may be wired in a series-parallel circuit which combines characteristics of the constituent circuit types to this combination circuit. Battery cells may be electrically connected in a virtually unlimited arrangement which may confer onto the system the electrical advantages associated with that arrangement such as high-voltage applications, high-current applications, or the like.

With continued reference to FIG. 1, battery 108 may include a plurality of battery modules. The battery modules may be wired together in series and in parallel. Battery 108 may include a center sheet which may include a thin barrier. The barrier may include a fuse connecting battery modules on either side of the center sheet. The fuse may be disposed in or on the center sheet and configured to connect to an electric circuit comprising a first battery module and therefore battery unit and cells. In general, and for the purposes of this disclosure, a fuse is an electrical safety device that operate to provide overcurrent protection of an electrical circuit. As a sacrificial device, its essential component is metal wire or strip that melts when too much current flows through it, thereby interrupting energy flow. The fuse may include a thermal fuse, mechanical fuse, blade fuse, expulsion fuse, spark gap surge arrestor, varistor, or a combination thereof

With continued reference to FIG. 1, system 100 includes a plurality of sensors 116a-c. As used in this disclosure, a “sensor” is a device that detects a phenomenon. In some cases, a sensor may detect a phenomenon and generate and/or transduce a signal or at least a datum of information representative of the phenomenon. In some cases, plurality of sensors 116a-c may be configured to detect a potential 120a-c of each cell of the plurality of cells 112a-c. As used in this disclosure, “electrical potential.” also referred to as “potential,” in this disclosure, is an electrical effort. Potential may also be considered an amount of work needed to move a unit of electric charge from a reference point to a specific point in an electric field. Accordingly, potential may be considered in units of work per charge, e.g. Joules / Coulombs or Volts. In some cases, plurality of sensors 116a-c may be configured to detect potential 120a-c over time for a duration. As used in this disclosure, a “duration” is an interval of time. In some cases, sensors 116a-c may detect potential in a manner that is substantially continuous over time. In some embodiments, duration may be no less than 60 seconds, 30 seconds, 10 seconds, 1 seconds, and/or 0.1 seconds. In some embodiments, duration may be no greater than 200 seconds, 300 seconds, 500 seconds, and/or 1,000 seconds. In some cases, substantially continuous detection of potential may be performed periodic at a rate that is sufficiently great (e.g., no less than 0.1 Hz, 1 Hz, 10 Hz, and the like).

With continued reference to FIG. 1, plurality of sensors 116a-c may include multimeter. Multimeter may be configured to measure voltage across a component, electrical current through a component, and/or resistance of a component. Multimeter may include separate sensors to measure each of the previously disclosed electrical characteristics such as voltmeter, ammeter, continuity meter and/or ohmmeter. Alternatively or additionally, plurality of sensors 116a-c may include a sensor or plurality thereof that may detect potential; detection may be performed using any suitable component, set of components, and/or mechanism for direct or indirect measurement and/or detection of potential, including without limitation comparators, analog to digital converters, any form of voltmeter, or the like. Plurality of sensors 116a-c may be configured to determine that a charge level of a battery cell is high/low based on a detected potential of that battery cell or portion of battery. Plurality of sensors 116a-c may include digital sensors, analog sensors, or a combination thereof. Sensors 116a-c may include digital-to-analog converters (DAC), analog-to-digital converters (ADC, A/D, A-to-D), a combination thereof, or other signal conditioning components described above.

Still referring to FIG. 1, in some embodiments plurality of sensors 116a-c may include thermocouples, thermistors, thermometers, passive infrared sensors, resistance temperature sensors (RTD’s), semiconductor based integrated circuits (IC), a combination thereof or another undisclosed sensor type, alone or in combination. Temperature, as measured by any number or combinations of sensors present within sensors 116a-c, may be measured in Fahrenheit (°F), Celsius (°C), Kelvin (°K), or another scale alone or in combination. Temperature measured by sensors 116a-c may comprise electrical signals which are transmitted to their appropriate destination wireless or through a wired connection.

Still referring to FIG. 1, in some embodiments, plurality of sensors 116a-c may include a sensor configured to detect gas that may be emitted during or after a catastrophic cell failure. “Catastrophic cell failure”, as used in this disclosure, is a malfunction of a battery cell, which may be an electrochemical cell, that renders the cell inoperable for its designed function, namely providing electrical energy to at least a portion of an electric aircraft. Byproducts of catastrophic cell failure may include gaseous discharge including oxygen, hydrogen, carbon dioxide, methane, carbon monoxide, a combination thereof, or another undisclosed gas, alone or in combination. Further sensor configured to detect vent gas from electrochemical cells may comprise a gas detector. For the purposes of this disclosure, a “gas detector” is a device used to detect a gas is present in an area. Gas detectors, and more specifically, the gas sensor that may be used in sensors 116a-c, may be configured to detect combustible, flammable, toxic, oxygen depleted, a combination thereof, or another type of gas alone or in combination. Gas sensor that may be present in sensors 116a-c may include a combustible gas, photoionization detectors, electrochemical gas sensors, ultrasonic sensors, metal-oxide-semiconductor (MOS) sensors, infrared imaging sensors, a combination thereof, or another undisclosed type of gas sensor alone or in combination. Sensors 116a-c may include sensors that are configured to detect non-gaseous byproducts of catastrophic cell failure including, in non-limiting examples, liquid chemical leaks including aqueous alkaline solution, ionomer, molten phosphoric acid, liquid electrolytes with redox shuttle and ionomer, and salt water, among others. Sensors 116a-c may include sensors that are configured to detect non-gaseous byproducts of catastrophic cell failure including, in non-limiting examples, electrical anomalies as detected by any of the previous disclosed sensors or components.

With continued reference to FIG. 1, plurality of sensors 116a-c may be configured to detect events where potential nears an upper potential threshold or lower potential threshold. Upper potential threshold may be stored in data storage system for comparison with an instant measurement taken by any combination of sensors 116a-c. Upper potential threshold may be calculated and calibrated based on factors relating to battery cell health, maintenance history, location within battery 108, designed application, and type, among others. Sensors 116a-c may measure potential at an instant, over a period of time, or periodically. Sensors 116a-c may be configured to operate at any of these detection modes, switch between modes, or simultaneous measure in more than one mode. Sensors 116a-c may, in some cases, detect events where potential nears lower voltage threshold. Lower voltage threshold may indicate power loss to or from an individual battery cell 112a-c or portion of the battery 108.

With continued reference to FIG. 1, plurality of sensors 116a-c may be disposed in or on a portion of battery 108 near battery modules and/or battery cells. First sensor 116a may be disposed in or on a first battery cell 112a and second sensor 116b may be disposed in or on a second battery cell 112b. Outputs from sensors 116a-c or any other component present within system may be analog or digital. Onboard or remotely located processors can convert those output signals from sensors 116a-c to a usable form by the destination of those signals. A usable form of output signals from sensors may be either digital, analog, a combination thereof, or an otherwise unstated form. Processing may be configured to trim, offset, or otherwise compensate outputs of sensors 116a-c. Based on sensor output, a processor can determine output to send to downstream component. Processor can include signal amplification, operational amplifier (OpAmp), filter, digital/analog conversion, linearization circuit, current-voltage change circuits, resistance change circuits such as Wheatstone Bridge, an error compensator circuit, a combination thereof or otherwise undisclosed components.

With continued reference to FIG. 1, as used in this disclosure, a “signal” is any intelligible representation of data, for example from one device to another. A signal may include an optical signal, a hydraulic signal, a pneumatic signal, a mechanical, signal, an electric signal, a digital signal, an analog signal and the like. In some cases, a signal may be used to communicate with computing device 104, for example by way of one or more ports. In some cases, a signal may be transmitted and/or received by a computing device for example by way of an input/output port. An analog signal may be digitized, for example by way of an analog to digital converter. In some cases, an analog signal may be processed, for example by way of any analog signal processing steps described in this disclosure, prior to digitization. In some cases, a digital signal may be used to communicate between two or more devices, including without limitation computing devices. In some cases, a digital signal may be communicated by way of one or more communication protocols, including without limitation internet protocol (IP), controller area network (CAN) protocols, serial communication protocols (e.g., universal asynchronous receiver-transmitter [UART]), parallel communication protocols (e.g., IEEE 128 [printer port]), and the like.

Still referring to FIG. 1, in some cases, system 100 may perform one or more signal processing steps on a potential 120a-c. For instance, system 100 may analyze, modify, and/or synthesize a signal representative of potential 120a-c in order to improve the signal, for instance by improving transmission, storage efficiency, or signal to noise ratio. Exemplary methods of signal processing may include analog, continuous time, discrete, digital, nonlinear, and statistical. Analog signal processing may be performed on non-digitized or analog signals. Exemplary analog processes may include passive filters, active filters, additive mixers, integrators, delay lines, compandors, multipliers, voltage-controlled filters, voltage-controlled oscillators, and phase-locked loops. Continuous-time signal processing may be used, in some cases, to process signals which varying continuously within a domain, for instance time. Exemplary non-limiting continuous time processes may include time domain processing, frequency domain processing (Fourier transform), and complex frequency domain processing. Discrete time signal processing may be used when a signal is sampled non-continuously or at discrete time intervals (i.e., quantized in time). Analog discrete-time signal processing may process a signal using the following exemplary circuits sample and hold circuits, analog time-division multiplexers, analog delay lines and analog feedback shift registers. Digital signal processing may be used to process digitized discrete-time sampled signals. Commonly, digital signal processing may be performed by a computing device or other specialized digital circuits, such as without limitation an application specific integrated circuit (ASIC), a field-programmable gate array (FPGA), or a specialized digital signal processor (DSP). Digital signal processing may be used to perform any combination of typical arithmetical operations, including fixed-point and floating-point, real-valued and complex-valued, multiplication and addition. Digital signal processing may additionally operate circular buffers and lookup tables. Further non-limiting examples of algorithms that may be performed according to digital signal processing techniques include fast Fourier transform (FFT), finite impulse response (FIR) filter, infinite impulse response (IIR) filter, and adaptive filters such as the Wiener and Kalman filters. Statistical signal processing may be used to process a signal as a random function (i.e., a stochastic process), utilizing statistical properties. For instance, in some embodiments, a signal may be modeled with a probability distribution indicating noise, which then may be used to reduce noise in a processed signal.

Still referring to FIG. 1, in some embodiments, plurality of sensors 116a-c may be further configured to detect potential 120a-c of each cell substantially starting when battery begins 108 discharging. As used in this disclosure, a battery is said to “discharge” when a substantial electric load is applied to the battery and energy stored within the battery is being consumed. In some cases, battery 108 may be configured to power an electric vehicle, for example without limitation an electric aircraft (e.g., electric vertical take-off and landing [eVTOL] aircraft). In some cases, discharge of battery 108 may begin when electric vehicle begins moving, for instance through propulsion provided by battery 108 powered motor(s). In some cases, system 100 may be used to predict and/or determine at least a weak cell within a duration of time during a beginning of a journey (e.g., flight). In some case, determining at least a weak cell early in during a journey may allow for better prediction methods regarding utilization of energy stored in battery 108 during the journey and/or over a life of vehicle. For example, in some cases, determining at least a weak cell may be used to predict a practical state of charge of battery 108 and/or provide a fuel gauge estimation for vehicle.

With continued reference to FIG. 1, computing device 104 may be in communicatively connected to plurality of sensors 116a-c, as described above. Computing device 104 may be in communication with plurality of sensors 116a-c by way of at least a network. Network may include any network described in this disclosure, for example without limitation controller area network (CAN), local area network (LAN), wide area network (WAN), Internet, wireless network (Wi-Fi), cellular network, and the like. In some cases, computing device 104 may be in communication with plurality of sensors 116a-c by way of one or more signals, for example without limitation electrical signals, optical signals, and the like. Plurality of sensors 116a-c may transmit plurality of potentials 120a-c for each of plurality of cells 112a-c to computing device 104. Computing device may receive potential 120a-c of each cell of plurality of cells 112a-c. In some cases, communication between sensors 116a-c and computing device may be achieved by way of signals, such as those described in detail above.

With continued reference to FIG. 1, computing device 104 is configured to determine at least an outlier cell 124 from plurality of cells 112a-c. As used in this disclosure, an “outlier cell” is a cell that is differs significantly according to one or more values. In some cases, determining at least an outlier cell 124 may be performed as a function of potential 120a-c of each cell of the plurality of cells 112a-c. In some cases, computing device 104 may determine at least an outlier 124 in part by determining at least a feature. As used in this disclosure, a “feature” is characteristic, property and/or attribute that may be extracted from a dataset. In some cases, a feature may be determined according to a predetermined process or algorithm. Alternative or additionally, in some cases, a feature may be determined and/or extracted using at least a machine-learning process such as a classifier. A “classifier,” as used in this disclosure is a machine-learning model, such as a mathematical model, neural net, or program generated by a machine learning algorithm known as a “classification algorithm,” as described in further detail below, that sorts inputs into categories or bins of data, outputting the categories or bins of data and/or labels associated therewith. A classifier may be configured to output at least a datum that labels or otherwise identifies a set of data that are clustered together, found to be close under a distance metric as described below, or the like. Computing device 104 and/or another device may generate a classifier using a classification algorithm, defined as a process whereby a computing device 104 derives a classifier from training data. Classification may be performed using, without limitation, linear classifiers such as without limitation logistic regression and/or naive Bayes classifiers, nearest neighbor classifiers such as k-nearest neighbors classifiers, support vector machines, least squares support vector machines, fisher’s linear discriminant, quadratic classifiers, decision trees, boosted trees, random forest classifiers, learning vector quantization, and/or neural network-based classifiers.

Still referring to FIG. 1, computing device 104 may be configured to generate a classifier using a Naïve Bayes classification algorithm. Naïve Bayes classification algorithm generates classifiers by assigning class labels to problem instances, represented as vectors of element values. Class labels are drawn from a finite set. Naïve Bayes classification algorithm may include generating a family of algorithms that assume that the value of a particular element is independent of the value of any other element, given a class variable. Naïve Bayes classification algorithm may be based on Bayes Theorem expressed as P(A/B)= P(B/A) P(A)÷P(B), where P(A/B) is the probability of hypothesis A given data B also known as posterior probability; P(B/A) is the probability of data B given that the hypothesis A was true; P(A) is the probability of hypothesis A being true regardless of data also known as prior probability of A; and P(B) is the probability of the data regardless of the hypothesis. A naïve Bayes algorithm may be generated by first transforming training data into a frequency table. Computing device 104 may then calculate a likelihood table by calculating probabilities of different data entries and classification labels. Computing device 104 may utilize a naïve Bayes equation to calculate a posterior probability for each class. A class containing the highest posterior probability is the outcome of prediction. Naïve Bayes classification algorithm may include a gaussian model that follows a normal distribution. Naïve Bayes classification algorithm may include a multinomial model that is used for discrete counts. Naïve Bayes classification algorithm may include a Bernoulli model that may be utilized when vectors are binary.

With continued reference to FIG. 1, computing device 104 may be configured to generate a classifier using a K-nearest neighbors (KNN) algorithm. A “K-nearest neighbors algorithm” as used in this disclosure, includes a classification method that utilizes feature similarity to analyze how closely out-of-sample- features resemble training data to classify input data to one or more clusters and/or categories of features as represented in training data; this may be performed by representing both training data and input data in vector forms, and using one or more measures of vector similarity to identify classifications within training data, and to determine a classification of input data. K-nearest neighbors algorithm may include specifying a K-value, or a number directing the classifier to select the k most similar entries training data to a given sample, determining the most common classifier of the entries in the database, and classifying the known sample; this may be performed recursively and/or iteratively to generate a classifier that may be used to classify input data as further samples. For instance, an initial set of samples may be performed to cover an initial heuristic and/or “first guess” at an output and/or relationship, which may be seeded, without limitation, using expert input received according to any process as described herein. As a non-limiting example, an initial heuristic may include a ranking of associations between inputs and elements of training data. Heuristic may include selecting some number of highest-ranking associations and/or training data elements.

With continued reference to FIG. 1, generating k-nearest neighbors algorithm may generate a first vector output containing a data entry cluster, generating a second vector output containing an input data, and calculate the distance between the first vector output and the second vector output using any suitable norm such as cosine similarity, Euclidean distance measurement, or the like. Each vector output may be represented, without limitation, as an n-tuple of values, where n is at least two values. Each value of n-tuple of values may represent a measurement or other quantitative value associated with a given category of data, or attribute, examples of which are provided in further detail below; a vector may be represented, without limitation, in n-dimensional space using an axis per category of value represented in n-tuple of values, such that a vector has a geometric direction characterizing the relative quantities of attributes in the n-tuple as compared to each other. Two vectors may be considered equivalent where their directions, and/or the relative quantities of values within each vector as compared to each other, are the same; thus, as a non-limiting example, a vector represented as [5, 10, 15] may be treated as equivalent, for purposes of this disclosure, as a vector represented as [1, 2, 3]. Vectors may be more similar where their directions are more similar, and more different where their directions are more divergent; however, vector similarity may alternatively or additionally be determined using averages of similarities between like attributes, or any other measure of similarity suitable for any n-tuple of values, or aggregation of numerical similarity measures for the purposes of loss functions as described in further detail below. Any vectors as described herein may be scaled, such that each vector represents each attribute along an equivalent scale of values. Each vector may be “normalized,” or divided by a “length” attribute, such as a length attribute 1 as derived using a Pythagorean norm:

$$l = \sqrt{\sum {}_{i = 0}^{n} {a}_{i} {}^{2} ,}$$

where ai is attribute number i of the vector. Scaling and/or normalization may function to make vector comparison independent of absolute quantities of attributes, while preserving any dependency on similarity of attributes; this may, for instance, be advantageous where cases represented in training data are represented by different quantities of samples, which may result in proportionally equivalent vectors with divergent values.

Still referring to FIG. 1, in some embodiments, computing device 104 may generate a classifier using a feature learning algorithm. A “feature learning algorithm,” as used in this disclosure, is a machine-learning algorithm that identifies associations between elements of data in a data set, which may include without limitation a training data set, where particular outputs and/or inputs are not specified. For instance, and without limitation, a feature learning algorithm may detect co-occurrences of sets of potential data, as defined above, with each other. Computing device may perform a feature learning algorithm by dividing potential data from a given battery into various subcombinations of such data to create potential data sets and evaluate which potential data sets tend to co-occur with which other determined battery performance; for instance, where potential data includes potential from individual cells 112a-c, computing device 104 may evaluate which features extracted from potential data co-occur with known weak cells. In an embodiment, feature learning algorithm may perform clustering of data.

Still referring to FIG. 1, in some cases, a feature may be significant in its relevance to a stated application, for example determining at least a weak cell within a battery. Exemplary non-limiting features include minimum potential and potential integral. In some embodiments, computing device 104 may be further configured to calculate a minimum potential for each cell of plurality of cells 108a-c. As used in this disclosure, a “minimum potential” is a lowest potential value of a plurality of potential values, for example a potential value over time for a duration.

Still referring to FIG. 1, in some embodiments, computing device 104 may be further configured to calculate a potential integral for each cell of plurality of cells 108a-c. As used in this disclosure, a “potential integral” is an integrated value of a potential value over time. In some cases, potential integral may be found through approximation, for example by using one or more of left rectangular approximation, right rectangular approximation, midpoint rectangular approximation, trapezoidal rule, Simpson’s rule, and the like.

Still referring to FIG. 1, in some embodiments, computing device 104 may be further configured to standardize the potential of each cell of the plurality of cells. As used in this disclosure, “standardizing” is a mathematical calculation used to determine relative differences between individuals within a population. Standardizing may include one or more of statistical standardizing, normalizing, unifying, and the like. In some cases, standardizing may include calculating a standard score. As used in this disclosure, a “standard score” is a number of standard deviations by which a value is above or below the mean value of what is being observed or measured. In some cases, calculating a standard score may include:

$$z = \frac{x - μ}{σ}$$

where, z is the standard score, x is a value, µ is a mean of a population, and σ is a standard deviation of the population. In some cases, calculating a standard score may require knowledge of a population’s mean and standard deviation. As this may be unrealistic, in some cases, calculating standard score includes:

$$z = \frac{x - \overline{x}}{S}$$

where, z is the standard score, x is a value, x̅ is a mean of a sample, and S is a standard deviation of the sample. In some embodiments, computing device 104 may calculate one or more of a mean potential and a standard deviation, for example in order to standardize potential data.

Still referring to FIG. 1, computing device 104 may be configured to determine the at least an outlier cell using a nearest neighbor algorithm. In some embodiments, a feature learning and/or clustering algorithm may be implemented, as a non-limiting example, using a k-means clustering algorithm. A “k-means clustering algorithm” as used in this disclosure, includes cluster analysis that partitions n observations or unclassified cluster data entries into k clusters in which each observation or unclassified cluster data entry belongs to the cluster with the nearest mean, using, for instance behavioral training set as described above. “Cluster analysis” as used in this disclosure, includes grouping a set of observations or data entries in way that observations or data entries in the same group or cluster are more similar to each other than to those in other groups or clusters. Cluster analysis may be performed by various cluster models that include connectivity models such as hierarchical clustering, centroid models such as k-means, distribution models such as multivariate normal distribution, density models such as density-based spatial clustering of applications with nose (DBSCAN) and ordering points to identify the clustering structure (OPTICS), subspace models such as biclustering, group models, graph-based models such as a clique, signed graph models, neural models, and the like. Cluster analysis may include hard clustering whereby each observation or unclassified cluster data entry belongs to a cluster or not. Cluster analysis may include soft clustering or fuzzy clustering whereby each observation or unclassified cluster data entry belongs to each cluster to a certain degree such as for example a likelihood of belonging to a cluster; for instance, and without limitation, a fuzzy clustering algorithm may be used to identify clustering of gene combinations with multiple disease states, and vice versa. Cluster analysis may include strict partitioning clustering whereby each observation or unclassified cluster data entry belongs to exactly one cluster. Cluster analysis may include strict partitioning clustering with outliers whereby observations or unclassified cluster data entries may belong to no cluster and may be considered outliers. Cluster analysis may include overlapping clustering whereby observations or unclassified cluster data entries may belong to more than one cluster. Cluster analysis may include hierarchical clustering whereby observations or unclassified cluster data entries that belong to a child cluster also belong to a parent cluster.

With continued reference to FIG. 1, computing device 104 may generate a k-means clustering algorithm receiving unclassified potential data or classified potential data and outputs a definite number of classified data entry clusters wherein the data entry clusters each contain cluster data entries. K-means algorithm may select a specific number of groups or clusters to output, identified by a variable “k.” Generating a k-means clustering algorithm includes assigning inputs containing unclassified data to a “k-group” or “k-cluster” based on feature similarity. Centroids of k-groups or k-clusters may be utilized to generate classified data entry cluster. K-means clustering algorithm may select and/or be provided “k” variable by calculating k-means clustering algorithm for a range of k values and comparing results. K-means clustering algorithm may compare results across different values of k as the mean distance between cluster data entries and cluster centroid. K-means clustering algorithm may calculate mean distance to a centroid as a function of k value, and the location of where the rate of decrease starts to sharply shift, this may be utilized to select a k value. Centroids of k-groups or k-cluster include a collection of feature values which are utilized to classify data entry clusters containing cluster data entries. K-means clustering algorithm may act to identify clusters of closely related potential data, which may be provided with battery cell cohort labels; this may, for instance, generate an initial set of battery cell cohort labels from an initial set of potential data of a large number of battery cells, and may also, upon subsequent iterations, identify new clusters to be provided new battery cell cohort labels, to which additional battery cell potential data may be classified, or to which previously used battery cell potential data may be reclassified.

With continued reference to FIG. 1, generating a k-means clustering algorithm may include generating initial estimates for k centroids which may be randomly generated or randomly selected from unclassified data input. K centroids may be utilized to define one or more clusters. K-means clustering algorithm may assign unclassified data to one or more k-centroids based on the squared Euclidean distance by first performing a data assigned step of unclassified data. K-means clustering algorithm may assign unclassified data to its nearest centroid based on the collection of centroids cᵢ of centroids in set C. Unclassified data may be assigned to a cluster based on argmin_{ci}_{∋}_{c} dist(ci,x)², where argmin includes argument of the minimum, ci includes a collection of centroids in a set C, and dist includes standard Euclidean distance. K-means clustering module may then recompute centroids by taking mean of all cluster data entries assigned to a centroid’s cluster. This may be calculated based on ci = 1/|Si|Σxi∋Si^{xi}. K-means clustering algorithm may continue to repeat these calculations until a stopping criterion has been satisfied such as when cluster data entries do not change clusters, the sum of the distances have been minimized, and/or some maximum number of iterations has been reached.

Still referring to FIG. 1, k-means clustering algorithm may be configured to calculate a degree of similarity index value. A “degree of similarity index value” as used in this disclosure, includes a distance measurement indicating a measurement between each data entry cluster generated by k-means clustering algorithm and a selected potential data set. Degree of similarity index value may indicate how close a particular potential data set and/or cell performance is to being classified by k-means algorithm to a particular cluster. K-means clustering algorithm may evaluate the distances of the potential data set and/or battery cell performance to the k-number of clusters output by k-means clustering algorithm. Short distances between a set of potential data and a cluster may indicate a higher degree of similarity between the set of potential data and a particular cluster. Longer distances between a set of cell performance and a cluster may indicate a lower degree of similarity between a potential data set and a particular cluster.

With continued reference to FIG. 1, k-means clustering algorithm selects a classified data entry cluster as a function of the degree of similarity index value. In an embodiment, k-means clustering algorithm may select a classified data entry cluster with the smallest degree of similarity index value indicating a high degree of similarity between a potential data set and the data entry cluster. Alternatively or additionally k-means clustering algorithm may select a plurality of clusters having low degree of similarity index values to potential data sets, indicative of greater degrees of similarity. Degree of similarity index values may be compared to a threshold number indicating a minimal and/or maximum degree of relatedness suitable for inclusion of a set of potential data in a cluster, where degree of similarity indices falling under the threshold number may be included as indicative of high degrees of relatedness. The above-described illustration of feature learning using k-means clustering is included for illustrative purposes only and should not be construed as limiting potential implementation of feature learning algorithms; persons skilled in the art, upon reviewing the entirety of this disclosure, will be aware of various additional or alternative feature learning approaches that may be used consistently with this disclosure.

With continued reference to FIG. 1, in some cases, outlier cells 124 may include cells that have potentials 120a-c significantly lesser than a median potential and cells that have potentials 120a-c significantly greater than the median potential. Said another way, in some cases, outlier cells 124 may include strong cells in addition to weak cells 128. Therefore computing device 104 is configured to filter outlier cells 124 to yield at least a weak cell 128. In some cases, computing device 104 may compare a potential 102a-c of at least an outlier cell 124 to one or more of a median potential, a mean potential, and/or a mode potential. For example, in some cases, subtracting one or more of a median potential, a mean potential, and/or a mode potential from a potential 120a-c of an outlier cell, in some cases, can result in a negative number when the outlier cell is a weak cell and a positive number when the outlier cell is a strong cell. Likewise, in some cases, dividing a potential 120a-c by one or more of a median potential, a mean potential, and/or a mode potential can result in a number less than 1 when the outlier cell is a weak cell and a number greater than 1 when the outlier cell is a string cell.

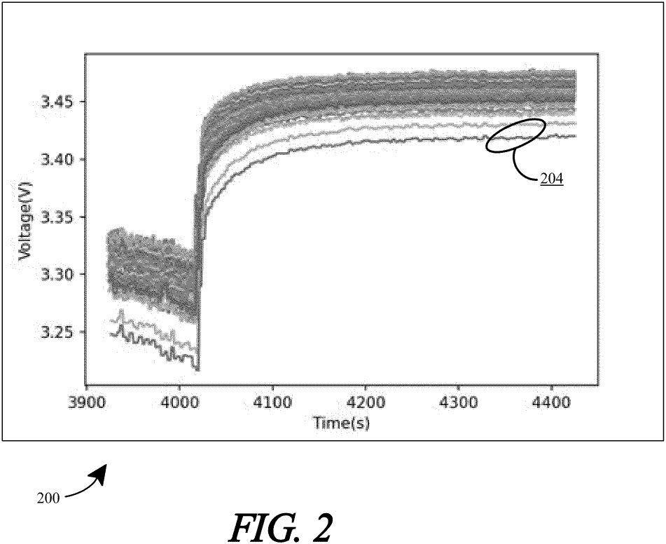

Referring now to FIG. 2, is a graph 200 illustrating potential over time for an exemplary battery with a plurality of cells as it discharges. Graph 200 includes time, in seconds, along a horizontal axis. Graph 200 includes potential, in voltage (V), along a vertical axis. Graph 200 includes a plurality of traces, wherein each trace represents potential of a battery cell. In an embodiment, weak cells 204, having lowest potential at end of discharge (e.g., time = 4400 seconds), may have lowest potential initially (e.g., time = 3950).

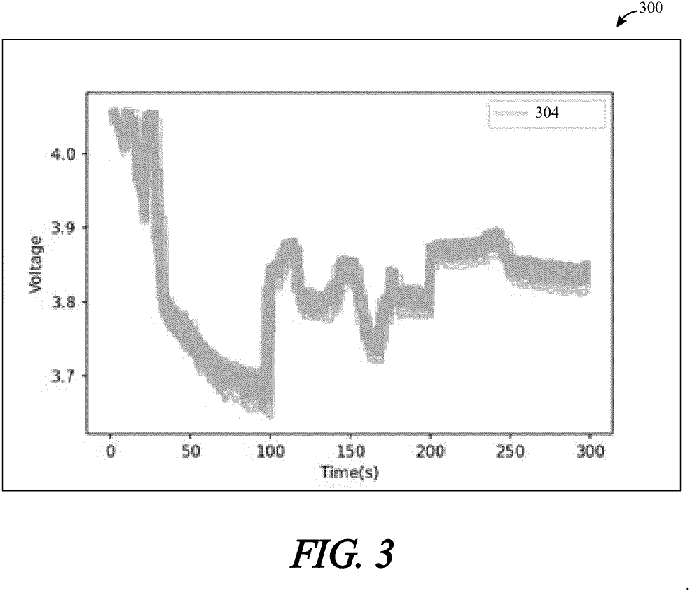

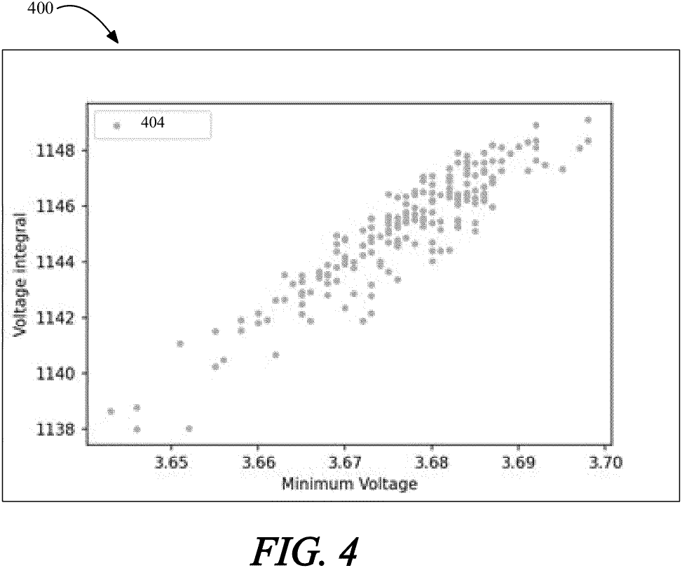

Referring now to FIG. 3 is a graph 300 illustrating exemplary data 304 representing potential over time for an exemplary battery with a plurality of cells as it discharges. Graph 300 includes time, in seconds, along a horizontal axis. Graph 300 includes potential, in voltage (V), along a vertical axis. Graph 300 includes a plurality of traces, wherein each trace represents potential of a battery cell. Unlike FIG. 2, it is not immediately clear from FIG. 3, which if any cells are weak cells. In order to determine weak cells from potentials illustrated in FIG. 3, additionally analysis may be performed, for example and with reference to FIGS. 4 - 6.

Referring now to FIG. 4 is a graph 400 illustrating exemplary data 404 representing potential integral and minimum potential for a plurality of cells of an exemplary battery as it discharges. Graph 400 includes minimum potential, in volts (V), along a horizontal axis. Minimum potential may be a lowest potential value along a potential trace. Graph 400 includes potential integral in volts times seconds (V*S), along a vertical axis. Potential integral may be an integral of a potential trace.

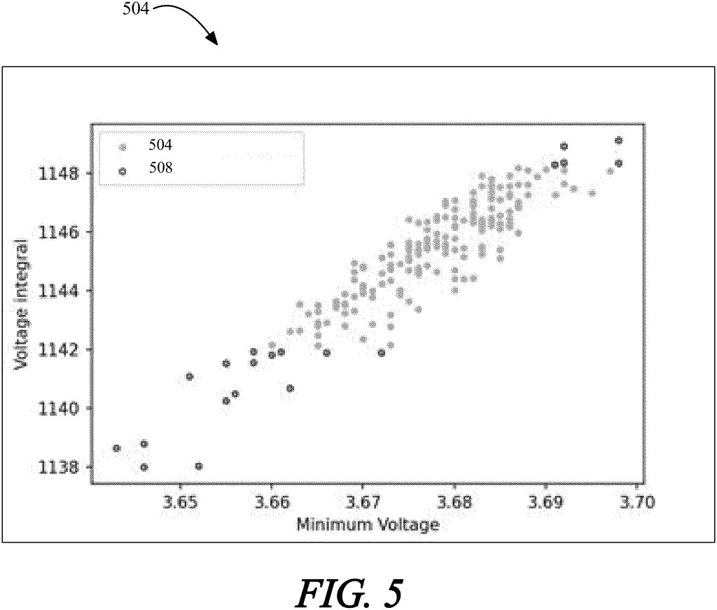

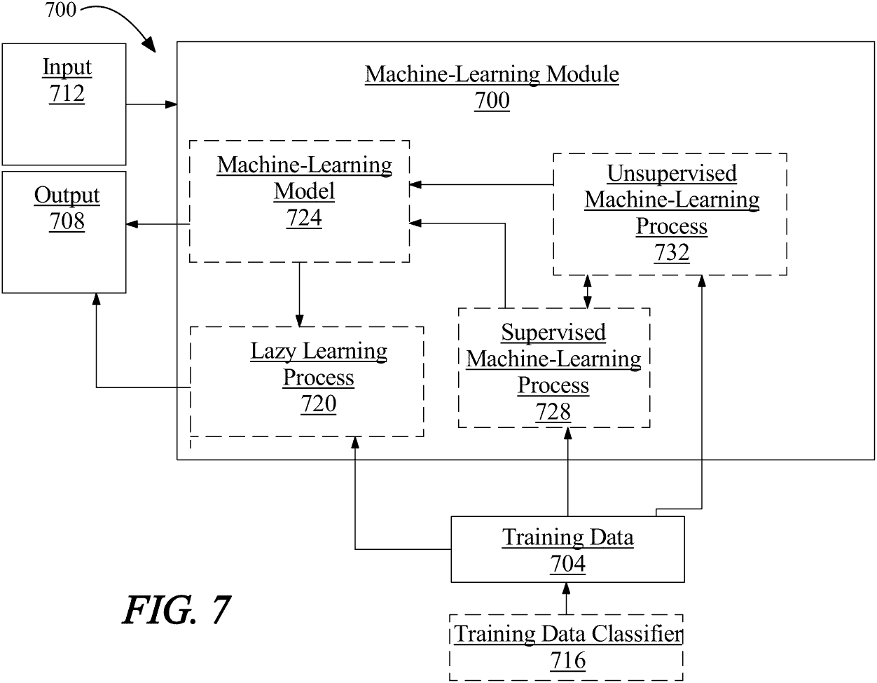

Referring now to FIG. 5 is a graph 500 illustrating exemplary data from FIG. 4. Graph 500 represents minimum potential, in volts (V), along a horizontal axis. Graph 500 represents potential integral in volts times seconds (V*S), along a vertical axis. Exemplary non-outlier data 504 and outlier data 508 is illustrated in graph 500. As can be seen in FIG. 5, outliers 508 may be seen at both extremes of distribution. Outliers 508 may be determined according to any method described in this disclosure, including with reference to FIGS. 1 and 7.

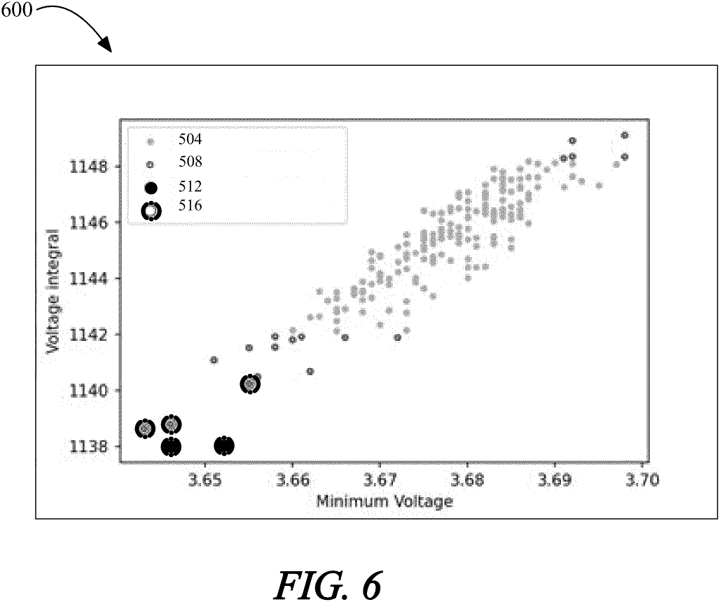

Referring now to FIG. 6 is a graph 600 illustrating exemplary data from FIG. 5. Graph 600 illustrates minimum potential, in volts (V), along a horizontal axis. Graph 600 illustrates potential integral in volts times seconds (V*S), along a vertical axis. Exemplary non-outlier data 604 and outlier data 608 is illustrated in graph 600. As can be seen in FIG. 5, outliers 608 may be seen at both extremes of distribution. Predicted weak cells 512 may be filtered from outliers 608, according to any method described in this disclosure. Predicted weak cells 512 are shown in graph 600. Actual weak cells 516 may be determined by measuring potential after utilization of battery. It can be seen from graph 600 that actual weak cells 516 and predicted weak cells 512 overlap.

Referring now to FIG. 7, an exemplary embodiment of a machine-learning module 700 that may perform one or more machine-learning processes as described in this disclosure is illustrated. Machine-learning module may perform determinations, classification, and/or analysis steps, methods, processes, or the like as described in this disclosure using machine learning processes. A “machine learning process,” as used in this disclosure, is a process that automatedly uses training data 704 to generate an algorithm that will be performed by a computing device/module to produce outputs 708 given data provided as inputs 712; this is in contrast to a nonmachine learning software program where the commands to be executed are determined in advance by a user and written in a programming language.

Still referring to FIG. 7, “training data,” as used herein, is data containing correlations that a machine-learning process may use to model relationships between two or more categories of data elements. For instance, and without limitation, training data 704 may include a plurality of data entries, each entry representing a set of data elements that were recorded, received, and/or generated together; data elements may be correlated by shared existence in a given data entry, by proximity in a given data entry, or the like. Multiple data entries in training data 704 may evince one or more trends in correlations between categories of data elements; for instance, and without limitation, a higher value of a first data element belonging to a first category of data element may tend to correlate to a higher value of a second data element belonging to a second category of data element, indicating a possible proportional or other mathematical relationship linking values belonging to the two categories. Multiple categories of data elements may be related in training data 704 according to various correlations; correlations may indicate causative and/or predictive links between categories of data elements, which may be modeled as relationships such as mathematical relationships by machine-learning processes as described in further detail below. Training data 704 may be formatted and/or organized by categories of data elements, for instance by associating data elements with one or more descriptors corresponding to categories of data elements. As a non-limiting example, training data 704 may include data entered in standardized forms by persons or processes, such that entry of a given data element in a given field in a form may be mapped to one or more descriptors of categories. Elements in training data 704 may be linked to descriptors of categories by tags, tokens, or other data elements; for instance, and without limitation, training data 704 may be provided in fixed-length formats, formats linking positions of data to categories such as comma-separated value (CSV) formats and/or self-describing formats such as extensible markup language (XML), JavaScript Object Notation (JSON), or the like, enabling processes or devices to detect categories of data.

Alternatively or additionally, and continuing to refer to FIG. 7, training data 704 may include one or more elements that are not categorized; that is, training data 704 may not be formatted or contain descriptors for some elements of data. Machine-learning algorithms and/or other processes may sort training data 704 according to one or more categorizations using, for instance, natural language processing algorithms, tokenization, detection of correlated values in raw data and the like; categories may be generated using correlation and/or other processing algorithms. As a non-limiting example, in a corpus of text, phrases making up a number “n” of compound words, such as nouns modified by other nouns, may be identified according to a statistically significant prevalence of n-grams containing such words in a particular order; such an n-gram may be categorized as an element of language such as a “word” to be tracked similarly to single words, generating a new category as a result of statistical analysis. Similarly, in a data entry including some textual data, a person’s name may be identified by reference to a list, dictionary, or other compendium of terms, permitting ad-hoc categorization by machine-learning algorithms, and/or automated association of data in the data entry with descriptors or into a given format. The ability to categorize data entries automatedly may enable the same training data 704 to be made applicable for two or more distinct machine-learning algorithms as described in further detail below. Training data 704 used by machine-learning module 700 may correlate any input data as described in this disclosure to any output data as described in this disclosure. As a non-limiting illustrative example inputs may include potentials from a plurality of cells and outputs may include indicators of known weak cells and/or non-weak cells.

Further referring to FIG. 7, training data may be filtered, sorted, and/or selected using one or more supervised and/or unsupervised machine-learning processes and/or models as described in further detail below; such models may include without limitation a training data classifier 716. Training data classifier 716 may include a “classifier,” which as used in this disclosure is a machine-learning model as defined below, such as a mathematical model, neural net, or program generated by a machine learning algorithm known as a “classification algorithm,” as described in further detail below, that sorts inputs into categories or bins of data, outputting the categories or bins of data and/or labels associated therewith. A classifier may be configured to output at least a datum that labels or otherwise identifies a set of data that are clustered together, found to be close under a distance metric as described below, or the like. Machine-learning module 700 may generate a classifier using a classification algorithm, defined as a processes whereby a computing device and/or any module and/or component operating thereon derives a classifier from training data 704. Classification may be performed using, without limitation, linear classifiers such as without limitation logistic regression and/or naive Bayes classifiers, nearest neighbor classifiers such as k-nearest neighbors classifiers, support vector machines, least squares support vector machines, fisher’s linear discriminant, quadratic classifiers, decision trees, boosted trees, random forest classifiers, learning vector quantization, and/or neural network-based classifiers.

Still referring to FIG. 7, machine-learning module 700 may be configured to perform a lazy-learning process 720 and/or protocol, which may alternatively be referred to as a “lazy loading” or “call-when-needed” process and/or protocol, may be a process whereby machine learning is conducted upon receipt of an input to be converted to an output, by combining the input and training set to derive the algorithm to be used to produce the output on demand. For instance, an initial set of simulations may be performed to cover an initial heuristic and/or “first guess” at an output and/or relationship. As a non-limiting example, an initial heuristic may include a ranking of associations between inputs and elements of training data 704. Heuristic may include selecting some number of highest-ranking associations and/or training data 704 elements. Lazy learning may implement any suitable lazy learning algorithm, including without limitation a K-nearest neighbors algorithm, a lazy naïve Bayes algorithm, or the like; persons skilled in the art, upon reviewing the entirety of this disclosure, will be aware of various lazy-learning algorithms that may be applied to generate outputs as described in this disclosure, including without limitation lazy learning applications of machine-learning algorithms as described in further detail below.

Alternatively or additionally, and with continued reference to FIG. 7, machine-learning processes as described in this disclosure may be used to generate machine-learning models 724. A “machine-learning model,” as used in this disclosure, is a mathematical and/or algorithmic representation of a relationship between inputs and outputs, as generated using any machine-learning process including without limitation any process as described above and stored in memory; an input is submitted to a machine-learning model 724 once created, which generates an output based on the relationship that was derived. For instance, and without limitation, a linear regression model, generated using a linear regression algorithm, may compute a linear combination of input data using coefficients derived during machine-learning processes to calculate an output datum. As a further non-limiting example, a machine-learning model 724 may be generated by creating an artificial neural network, such as a convolutional neural network comprising an input layer of nodes, one or more intermediate layers, and an output layer of nodes. Connections between nodes may be created via the process of “training” the network, in which elements from a training data 704 set are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning.

Still referring to FIG. 7, machine-learning algorithms may include at least a supervised machine-learning process 728. At least a supervised machine-learning process 728, as defined herein, include algorithms that receive a training set relating a number of inputs to a number of outputs, and seek to find one or more mathematical relations relating inputs to outputs, where each of the one or more mathematical relations is optimal according to some criterion specified to the algorithm using some scoring function. For instance, a supervised learning algorithm may include potential values from a plurality of cells as described above as inputs, indication of actual known weak cells as outputs, and a scoring function representing a desired form of relationship to be detected between inputs and outputs; scoring function may, for instance, seek to maximize the probability that a given input and/or combination of elements inputs is associated with a given output to minimize the probability that a given input is not associated with a given output. Scoring function may be expressed as a risk function representing an “expected loss” of an algorithm relating inputs to outputs, where loss is computed as an error function representing a degree to which a prediction generated by the relation is incorrect when compared to a given input-output pair provided in training data 704. Persons skilled in the art, upon reviewing the entirety of this disclosure, will be aware of various possible variations of at least a supervised machine-learning process 728 that may be used to determine relation between inputs and outputs. Supervised machine-learning processes may include classification algorithms as defined above.

Further referring to FIG. 7, machine learning processes may include at least an unsupervised machine-learning processes 732. An unsupervised machine-learning process, as used herein, is a process that derives inferences in datasets without regard to labels; as a result, an unsupervised machine-learning process may be free to discover any structure, relationship, and/or correlation provided in the data. Unsupervised processes may not require a response variable; unsupervised processes may be used to find interesting patterns and/or inferences between variables, to determine a degree of correlation between two or more variables, or the like.

Still referring to FIG. 7, machine-learning module 700 may be designed and configured to create a machine-learning model 724 using techniques for development of linear regression models. Linear regression models may include ordinary least squares regression, which aims to minimize the square of the difference between predicted outcomes and actual outcomes according to an appropriate norm for measuring such a difference (e.g. a vector-space distance norm); coefficients of the resulting linear equation may be modified to improve minimization. Linear regression models may include ridge regression methods, where the function to be minimized includes the least-squares function plus term multiplying the square of each coefficient by a scalar amount to penalize large coefficients. Linear regression models may include least absolute shrinkage and selection operator (LASSO) models, in which ridge regression is combined with multiplying the least-squares term by a factor of 1 divided by double the number of samples. Linear regression models may include a multi-task lasso model wherein the norm applied in the least-squares term of the lasso model is the Frobenius norm amounting to the square root of the sum of squares of all terms. Linear regression models may include the elastic net model, a multi-task elastic net model, a least angle regression model, a LARS lasso model, an orthogonal matching pursuit model, a Bayesian regression model, a logistic regression model, a stochastic gradient descent model, a perceptron model, a passive aggressive algorithm, a robustness regression model, a Huber regression model, or any other suitable model that may occur to persons skilled in the art upon reviewing the entirety of this disclosure. Linear regression models may be generalized in an embodiment to polynomial regression models, whereby a polynomial equation (e.g. a quadratic, cubic or higher-order equation) providing a best predicted output/actual output fit is sought; similar methods to those described above may be applied to minimize error functions, as will be apparent to persons skilled in the art upon reviewing the entirety of this disclosure.

Continuing to refer to FIG. 7, machine-learning algorithms may include, without limitation, linear discriminant analysis. Machine-learning algorithm may include quadratic discriminate analysis. Machine-learning algorithms may include kernel ridge regression. Machine-learning algorithms may include support vector machines, including without limitation support vector classification-based regression processes. Machine-learning algorithms may include stochastic gradient descent algorithms, including classification and regression algorithms based on stochastic gradient descent. Machine-learning algorithms may include nearest neighbors algorithms. Machine-learning algorithms may include various forms of latent space regularization such as variational regularization. Machine-learning algorithms may include Gaussian processes such as Gaussian Process Regression. Machine-learning algorithms may include cross-decomposition algorithms, including partial least squares and/or canonical correlation analysis. Machine-learning algorithms may include naïve Bayes methods. Machine-learning algorithms may include algorithms based on decision trees, such as decision tree classification or regression algorithms. Machine-learning algorithms may include ensemble methods such as bagging meta-estimator, forest of randomized tress, AdaBoost, gradient tree boosting, and/or voting classifier methods. Machine-learning algorithms may include neural net algorithms, including convolutional neural net processes.

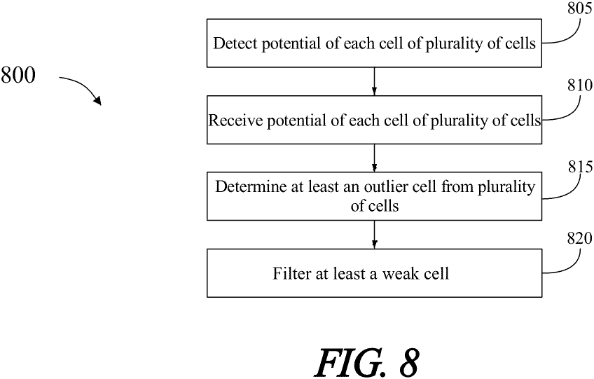

Referring now to FIG. 8, is a flow diagram of a method 800 of determining at least a weak cell of at least a battery is illustrated by way of a flow diagram. Battery may include any battery described in this disclosure, including for example FIGS. 1 - 7. At step 805, method 800 includes detecting, using a plurality of sensors, a potential of each cell of a plurality of cells of a battery over time for a duration. Plurality of sensors may include any sensors described in this disclosure, including for example and with reference to FIGS. 1 - 7. Potential may include any potential described in this disclosure, including for example and with reference to FIGS. 1 - 7. Plurality of cells may include any cells described in this disclosure, including for example and with reference to FIGS. 1 - 7. Duration may include any duration described in this disclosure, including for example and with reference to FIGS. 1 - 7. In some embodiments, duration may be no less than 10 seconds and may be no greater than 1,000 seconds. In some embodiments, at least a cell of the plurality of cells may include a pouch cell. Pouch cell may include any pouch cell described in this disclosure, for example with reference to FIGS. 1 - 7.

With continued reference to FIG. 8, at step 810, method 800 includes receiving, using a computing device, potential of each cell of plurality of cells. Computing device may include any computing device described in this disclosure, including for example FIGS. 1 - 7 and 9.

With continued reference to FIG. 8, at step 815, method 800 includes determining, using computing device, at least an outlier cell from plurality of cells, as a function of potential of each cell of the plurality of cells, Outlier cell may include any outlier cell described in this disclosure, including for example FIGS. 1 - 7.

With continued reference to FIG. 8, at step 820, method 800 includes filtering, using computing device, at least a weak cell as a function of the at least an outlier cell. Weak cell may include any weak cell described in this disclosure, including for example and with reference to FIGS. 1 - 7.

Still referring to FIG. 8, method 800 may include detecting, using plurality of sensors, potential of each cell substantially starting when battery begins discharging. Discharging may include any discharging described in this disclosure, including for example and with reference to FIGS. 1 - 7.

Still referring to FIG. 8, method 800 may include calculating, using computing device, a minimum potential for each cell of plurality of cells. Minimum potential may include any minimum potential described in this disclosure, including for example and with reference to FIGS. 1 - 7.

Still referring to FIG. 8, method 800 may include calculating, using computing device, a potential integral for each cell of plurality of cells. Potential integral may include any potential integral described in this disclosure, including for example and with reference to FIGS. 1 - 7.

Still referring to FIG. 8, method 800 may include standardizing, using computing device, potential of each cell of plurality of cells. Standardizing may include any standardizing described in this disclosure, including for example and with reference to FIGS. 1 - 7.

Still referring to FIG. 8, method 800 may include determining, using computing device, at least an outlier cell using a nearest neighbor algorithm. Nearest neighbor algorithm may include any nearest neighbor algorithm described in this disclosure, including for example and with reference to FIGS. 1 - 7.

Still referring to FIG. 8, method 800, may include determining, using computing device, at least an outlier cell by calculating a mean potential and a standard deviation. Mean potential may include any mean potential described in this disclosure, including for example and with reference to FIGS. 1 - 7. Standard deviation may include any standard deviation described in this disclosure, including for example and with reference to FIGS. 1 - 7.

Still referring to FIG. 8, method 800, may additionally include calculating, using computing device, at least a feature as function of potential of each cell of the plurality of cells. Feature may include any feature described in this disclosure, including with reference to FIGS. 1 - 7.

It is to be noted that any one or more of the aspects and embodiments described herein may be conveniently implemented using one or more machines (e.g., one or more computing devices that are utilized as a user computing device for an electronic document, one or more server devices, such as a document server, etc.) programmed according to the teachings of the present specification, as will be apparent to those of ordinary skill in the computer art. Appropriate software coding can readily be prepared by skilled programmers based on the teachings of the present disclosure, as will be apparent to those of ordinary skill in the software art. Aspects and implementations discussed above employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device) and that causes the machine to perform any one of the methodologies and/or embodiments described herein. Examples of a machine-readable storage medium include, but are not limited to, a magnetic disk, an optical disc (e.g., CD, CD-R, DVD, DVD-R, etc.), a magneto-optical disk, a read-only memory “ROM” device, a random access memory “RAM” device, a magnetic card, an optical card, a solid-state memory device, an EPROM, an EEPROM, and any combinations thereof. A machine-readable medium, as used herein, is intended to include a single medium as well as a collection of physically separate media, such as, for example, a collection of compact discs or one or more hard disk drives in combination with a computer memory. As used herein, a machine-readable storage medium does not include transitory forms of signal transmission.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

Examples of a computing device include, but are not limited to, an electronic book reading device, a computer workstation, a terminal computer, a server computer, a handheld device (e.g., a tablet computer, a smartphone, etc.), a web appliance, a network router, a network switch, a network bridge, any machine capable of executing a sequence of instructions that specify an action to be taken by that machine, and any combinations thereof. In one example, a computing device may include and/or be included in a kiosk.

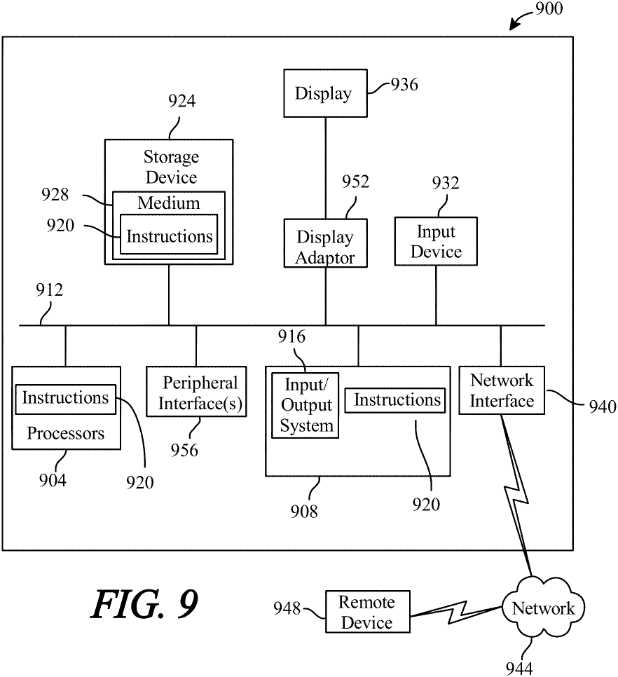

FIG. 9 shows a diagrammatic representation of one embodiment of a computing device in the exemplary form of a computer system 900 within which a set of instructions for causing a control system to perform any one or more of the aspects and/or methodologies of the present disclosure may be executed. It is also contemplated that multiple computing devices may be utilized to implement a specially configured set of instructions for causing one or more of the devices to perform any one or more of the aspects and/or methodologies of the present disclosure. Computer system 900 includes a processor 904 and a memory 908 that communicate with each other, and with other components, via a bus 912. Bus 912 may include any of several types of bus structures including, but not limited to, a memory bus, a memory controller, a peripheral bus, a local bus, and any combinations thereof, using any of a variety of bus architectures.

Processor 904 may include any suitable processor, such as without limitation a processor incorporating logical circuitry for performing arithmetic and logical operations, such as an arithmetic and logic unit (ALU), which may be regulated with a state machine and directed by operational inputs from memory and/or sensors; processor 904 may be organized according to Von Neumann and/or Harvard architecture as a non-limiting example. Processor 904 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating-point unit (FPU), and/or system on a chip (SoC).

Memory 908 may include various components (e.g., machine-readable media) including, but not limited to, a random-access memory component, a read only component, and any combinations thereof. In one example, a basic input/output system 916 (BIOS), including basic routines that help to transfer information between elements within computer system 900, such as during start-up, may be stored in memory 908. Memory 908 may also include (e.g., stored on one or more machine-readable media) instructions (e.g., software) 920 embodying any one or more of the aspects and/or methodologies of the present disclosure. In another example, memory 908 may further include any number of program modules including, but not limited to, an operating system, one or more application programs, other program modules, program data, and any combinations thereof.

Computer system 900 may also include a storage device 924. Examples of a storage device (e.g., storage device 924) include, but are not limited to, a hard disk drive, a magnetic disk drive, an optical disc drive in combination with an optical medium, a solid-state memory device, and any combinations thereof. Storage device 924 may be connected to bus 912 by an appropriate interface (not shown). Example interfaces include, but are not limited to, SCSI, advanced technology attachment (ATA), serial ATA, universal serial bus (USB), IEEE 1394 (FIREWIRE), and any combinations thereof. In one example, storage device 924 (or one or more components thereof) may be removably interfaced with computer system 900 (e.g., via an external port connector (not shown)). Particularly, storage device 924 and an associated machine-readable medium 928 may provide nonvolatile and/or volatile storage of machine-readable instructions, data structures, program modules, and/or other data for computer system 900. In one example, software 920 may reside, completely or partially, within machine-readable medium 928. In another example, software 920 may reside, completely or partially, within processor 904.

Computer system 900 may also include an input device 932. In one example, a user of computer system 900 may enter commands and/or other information into computer system 900 via input device 932. Examples of an input device 932 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), a touchscreen, and any combinations thereof. Input device 932 may be interfaced to bus 912 via any of a variety of interfaces (not shown) including, but not limited to, a serial interface, a parallel interface, a game port, a USB interface, a FIREWIRE interface, a direct interface to bus 912, and any combinations thereof. Input device 932 may include a touch screen interface that may be a part of or separate from display 936, discussed further below. Input device 932 may be utilized as a user selection device for selecting one or more graphical representations in a graphical interface as described above.

A user may also input commands and/or other information to computer system 900 via storage device 924 (e.g., a removable disk drive, a flash drive, etc.) and/or network interface device 940. A network interface device, such as network interface device 940, may be utilized for connecting computer system 900 to one or more of a variety of networks, such as network 944, and one or more remote devices 948 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network, such as network 944, may employ a wired and/or a wireless mode of communication. In general, any network topology may be used. Information (e.g., data, software 920, etc.) may be communicated to and/or from computer system 900 via network interface device 940.

Computer system 900 may further include a video display adapter 952 for communicating a displayable image to a display device, such as display device 936. Examples of a display device include, but are not limited to, a liquid crystal display (LCD), a cathode ray tube (CRT), a plasma display, a light emitting diode (LED) display, and any combinations thereof. Display adapter 952 and display device 936 may be utilized in combination with processor 904 to provide graphical representations of aspects of the present disclosure. In addition to a display device, computer system 900 may include one or more other peripheral output devices including, but not limited to, an audio speaker, a printer, and any combinations thereof. Such peripheral output devices may be connected to bus 912 via a peripheral interface 956. Examples of a peripheral interface include, but are not limited to, a serial port, a USB connection, a FIREWIRE connection, a parallel connection, and any combinations thereof.

The foregoing has been a detailed description of illustrative embodiments of the invention. Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve methods, systems, and software according to the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A system for determining at least a weak cell of at least a battery, the system comprising:
a battery comprising a plurality of cells;
a plurality of sensors configured to detect a potential of each cell of the plurality of cells for a duration; and
a computing device configured to:
receive the potential of each cell of the plurality of cells;
determine at least an outlier cell from the plurality of cells as a function of the potential of each cell of the plurality of cells; and
filter the at least a weak cell as a function of the at least an outlier cell.

2. The system of claim 1, wherein the duration is no less than 1 second and no greater than 1,000 seconds.

3. The system of claim 1, wherein the plurality of sensors is further configured to detect the potential of each cell starting when the battery begins discharging.

4. The system of claim 1, wherein the computing device is further configured to calculate a minimum potential for each cell of the plurality of cells.

5. The system of claim 1, wherein the computing device is further configured to calculate a potential integral for each cell of the plurality of cells.

6. The system of claim 1, wherein the computing device is further configured to standardize the potential of each cell of the plurality of cells.

7. The system of claim 1, wherein the computing device is further configured to determine the at least an outlier cell using a classification algorithm.

8. The system of claim 1, wherein the computing device is further configured to determine the at least an outlier cell by calculating a mean potential and a standard deviation.

9. The system of claim 1, wherein the computing device is further configured to calculate at least a feature as function of the potential of each cell of the plurality of cells.

10. The system of claim 1, wherein at least a cell of the plurality of cells comprises a pouch cell.

11. A method of determining at least a weak cell of at least a battery, the method comprising:
detecting, using a plurality of sensors, a potential of each cell of a plurality of cells of a battery for a duration;
receiving, using a computing device, the potential of each cell of the plurality of cells;
determining, using the computing device, at least an outlier cell from the plurality of cells as a function of the potential of each cell of the plurality of cells; and
filtering, using the computing device, the at least a weak cell as a function of the at least an outlier cell.

12. The method of claim 11, wherein the duration is no less than 1 second and no greater than 1,000 seconds.

13. The method of claim 11, further comprising detecting, using the plurality of sensors, the potential of each cell starting when the battery begins discharging.

14. The method of claim 11, further comprising calculating, using the computing device, a minimum potential for each cell of the plurality of cells.

15. The method of claim 11, further comprising calculating, using the computing device, a potential integral for each cell of the plurality of cells.

16. The method of claim 11, further comprising standardizing, using the computing device, the potential of each cell of the plurality of cells.

17. The method of claim 11, further comprising determining, using the computing device, the at least an outlier cell using a classification algorithm.

18. The method of claim 11, further comprising determining, using the computing device, the at least an outlier cell by calculating a mean potential and a standard deviation.

19. The method of claim 11, further comprising calculating, using the computing device, at least a feature as function of potential of each cell of the plurality of cells.

20. The method of claim 11, wherein at least a cell of the plurality of cells comprises a pouch cell.
